(19) United States
(12) Patent Application Publication
(10) Pub. No.: US 2008/0029244 A1
(43) Pub. Date: Feb. 7, 2008

(54) HEAT SINKS FOR DISSIPATING A THERMAL LOAD

(76) Inventors: Don A. Gilliland, Rochester, MN (US); Cary M. Huettner, Rochester, MN (US)

Correspondence Address: IBM (ROC-BLF), C/O BIGGERS & OHANIAN, LLP, P.O. BOX 1469, AUSTIN, TX, 78767-1469, US

(21) Appl. No.: 11/461,921

(22) Filed: Aug. 2, 2006

(51) Int. Cl. H05K 7/20

(52) U.S. Cl. 165/80.4; 165/80.3; 361/699

(57) ABSTRACT

Heat sinks for dissipating a thermal load are disclosed that include a heat sink base having a thermal base channel inside the heat sink base, the heat sink base capable of receiving a thermal load from a thermal source, heat-dissipating fins mounted on the heat sink base, each heat-dissipating fin having a thermal fin channel inside the heat-dissipating fin, and a thermal transport within the thermal base channel and the thermal fin channel, the thermal transport capable of transferring the thermal load from the heat sink base to the heat-dissipating fins. Methods for parallel dissipation of a thermal load are disclosed that include receiving, in a heat sink base, a thermal load from a thermal source, transferring the thermal load to heat-dissipating fins mounted on the heat sink base through a conductive heat path, and transferring the thermal load to the heat-dissipating fins through a convective heat path.

### BACKGROUND OF THE INVENTION

1. Field of the Invention

The field of the invention is heat sinks for dissipating a thermal load, parallel dissipation of a thermal load, and convective dissipation of a thermal load.

2. Description of Related Art

The development of the EDVAC computer system of 1948 is often cited as the beginning of the computer era. Since that time, users have relied on computer systems to simplify the process of information management. Today's computer systems are much more sophisticated than early systems such as the EDVAC. Such modern computer systems deliver powerful computing resources to provide a wide range of information management capabilities through the use of computer software such as database management systems, word processors, spreadsheets, client/server applications, web services, and so on.

In order to deliver powerful computing resources, computer architects must design powerful computer processors and high-speed memory modules. Current computer processors, for example, are capable of executing billions of computer program instructions per second. Operating these computer processors and memory modules requires a significant amount of power. Often processors can consume over 100 watts during operation. Consuming significant amounts of power generates a considerable amount of heat. Unless the heat is removed, the heat generated by a computer processor or memory module may degrade or destroy the component's functionality.

To prevent the degradation or destruction of an electronic component, a computer architect may remove heat from the electronic component by using traditional heat sinks or liquid metal cooling technologies. Traditional heat sinks have fins for dissipating heat into the environment surrounding the heat sink. Traditional heat sinks absorb the heat from an electronic component and transfer the heat to the heat-dissipating fins by conduction. The drawback of traditional heat sinks is that such heat sinks do not take advantage of more advanced cooling solutions provided by liquid metal cooling technologies.

Liquid metal cooling technologies pass liquid metal adjacent to an electronic component to absorb heat and then quickly transfer the liquid metal a few centimeters away to a nearby heat exchanger such as, for example, a traditional heat sink to cool the liquid metal. Transferring the liquid metal away from the electronic component quickly removes the heat from the location of the component. The cooled liquid metal is then returned to the processor or memory module to start the cycle again. The drawback to liquid metal cooling technologies is that such technologies require a pump for transferring the liquid metal from the heat source to the heat exchanger that may often fail. When the pump fails, the electronic component will often be destroyed before the computer system can be shutdown and the pump replaced.

### SUMMARY OF THE INVENTION

Heat sinks for dissipating a thermal load are disclosed that include a heat sink base having a thermal base channel inside the heat sink base, the heat sink base capable of receiving a thermal load from a thermal source, heat-dissipating fins mounted on the heat sink base, each heat-dissipating fin having a thermal fin channel inside the heat-dissipating fin, and a thermal transport within the thermal base channel and the thermal fin channel, the thermal transport capable of transferring the thermal load from the heat sink base to the heat-dissipating fins.

Methods are disclosed for parallel dissipation of a thermal load are disclosed that include receiving, in a heat sink base, a thermal load from a thermal source, transferring the thermal load to heat-dissipating fins mounted on the heat sink base through a conductive heat path, and transferring the thermal load to the heat-dissipating fins through a convective heat path.

Methods are disclosed for convective dissipation of a thermal load that include providing a convective heat path through a heat sink base and a plurality of fins mounted on the base, and passing a thermal transport carrying a thermal load through the convective heat path.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth an exploded perspective view of an exemplary heat sink for dissipating a thermal load according to embodiments of the present invention.

FIG. 2 sets forth an exploded perspective view of an exemplary heat sink base useful in a heat sink for dissipating a thermal load according to embodiments of the present invention.

FIG. 3 sets forth an exploded perspective view of an exemplary heat sink base useful in a heat sink for dissipating a thermal load according to embodiments of the present invention.

FIG. 4 sets forth an exploded perspective view of a further exemplary heat sink for dissipating a thermal load according to embodiments of the present invention.

FIG. 5 sets forth a perspective view of a further exemplary heat sink for dissipating a thermal load according to embodiments of the present invention.

FIG. 6 sets forth a flow chart illustrating an exemplary method for parallel dissipation of a thermal load according to embodiments of the present invention.

FIG. 7 sets forth a flow chart illustrating a further exemplary method for parallel dissipation of a thermal load according to embodiments of the present invention.

FIG. 8 sets forth a flow chart illustrating an exemplary method for convective dissipation of a thermal load according to embodiments of the present invention.

FIG. 9 sets forth a flow chart illustrating a further exemplary method for convective dissipation of a thermal load according to embodiments of the present invention.

FIG. 10 sets forth a flow chart illustrating a further exemplary method for convective dissipation of a thermal load according to embodiments of the present invention.

### DETAILED DESCRIPTION OF EXEMPLARY EMBODIMENTS

### Detailed Description

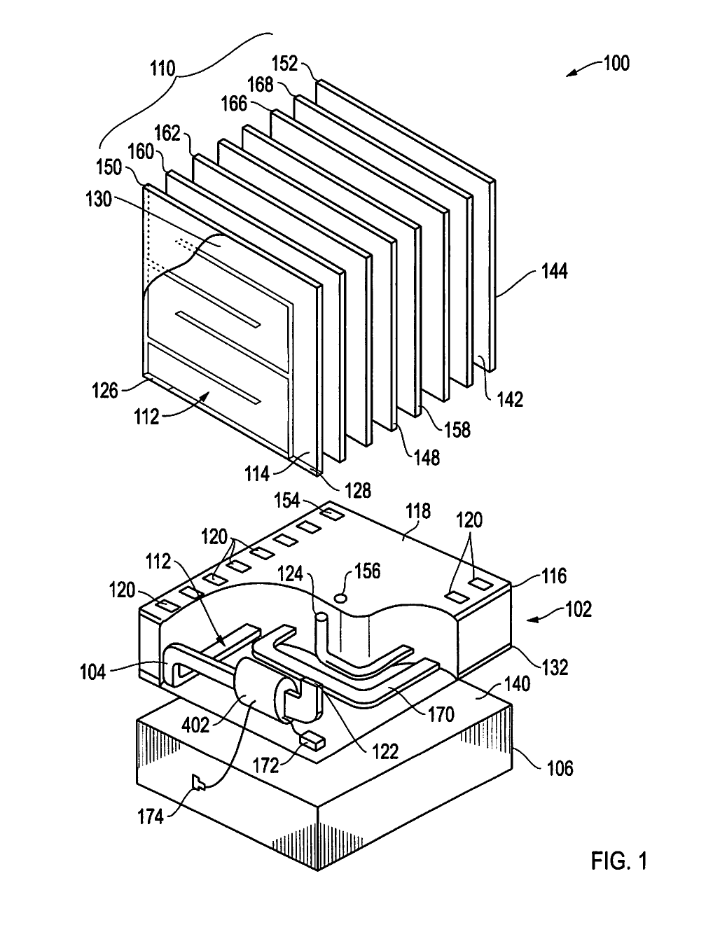

Exemplary heat sinks for dissipating a thermal load, exemplary methods for parallel dissipation of a thermal load, and exemplary methods for convective dissipation of a thermal load according to embodiments of the present invention are described with reference to the accompanying drawings, beginning with FIG. 1. FIG. 1 sets forth an exploded perspective view of an exemplary heat sink (100) for dissipating a thermal load according to embodiments of the present invention. The thermal load is the thermal energy generated by a thermal source (106) such as, for example, a computer processor or memory chip. A measure of thermal load is typically expressed in units of Joules. The rate at which a thermal source produces a thermal load over time is typically expressed in units of Watts.

In the example of FIG. 1, the heat sink (100) is a thermal conductor configured to absorb and dissipate the thermal load from the thermal source (106) thermally connected with the heat sink (100). Thermal conductors used in designing the heat sink (100) may include, for example, aluminum, copper, silver, aluminum silicon carbide, or carbon-based composites. Heat sink (100) absorbs the thermal load from the thermal source through thermal conduction. When thermally connected to the thermal source (106), the heat sink (100) provides additional thermal mass, cooler than the thermal source (106), into which the thermal load may flow. After absorbing the thermal load, the heat sink (100) dissipates the thermal load through thermal convection and thermal radiation into the air surrounding the heat sink (100). Increasing the surface area of the heat sink (100) typically increases the rate of dissipating the thermal load. The surface area of the heat sink (100) may be increased by enlarging a base of the heat sink or increasing the number of heat-dissipating fins.

To transfer the thermal load to the fins for heat-dissipation, the exemplary heat sink (100) of FIG. 1 provides two heat transfer paths—a conductive heat path and a convective heat path. The conductive heat path is the path through solid portions of the exemplary heat sink (100) through which the thermal load is transferred by heat conduction. The convective heat path is the path through a liquid portion of the exemplary heat sink (100) that carries the thermal load from the base of the heat sink (100) to the heat-dissipating fins. The liquid portion of the exemplary heat sink (100) is a thermal transport. The thermal transport is a thermally conductive fluid such as, for example, liquid metal or the family of perfluorinated liquids developed by 3M™ generally referred to as Fluorinert™.

The exemplary heat sink (100) of FIG. 1 includes a heat sink base (102) having a thermal base channel (104) inside the heat sink base. The heat sink base (102) is a thermal conductor capable of receiving a thermal load from a thermal source (106). The thermal base channel (104) is a channel through the heat sink base (102) capable of passing a thermal transport. The thermal base channel (104) provides a convective path for transferring the thermal load to heat-dissipating fins of the heat sink (100). As the heat sink base (102) receives the thermal load from the thermal source (106) by conduction, the thermal transport in the thermal base channel (104) also receives the thermal load by conduction. After receiving the thermal load, the thermal transport then transfers the thermal load to heat-dissipating fins by passing through the thermal base channel (104).

In the exemplary heat sink (100) of FIG. 1, the thermal base channel (104) extends through the heat sink base (102) in a swirling pattern. Although FIG. 1 illustrates the thermal base channel (104) extending through the heat sink base (102) in a swirling pattern, such an illustration is for explanation only and not for limitation. In fact, the thermal base channel (104) may extend through the heat sink base (102) in a variety of configurations. The particular configuration in which a thermal base channel (104) extends through the heat sink base (102) typically depends on the distribution of the thermal load along surface (140) of the thermal source (106). Heat sink designers may extend more of the thermal base channel (104) through regions of the heat sink base (102) adjacent to regions of surface (140) having a higher thermal load than other regions of surface (140). Such configurations may optimize the transfer of the thermal load into the convective heat path formed by the thermal base channel (104).

The exemplary heat sink base (102) of FIG. 1 includes a heat distribution plate (132) adjacent to the thermal source (106) and adjacent to the thermal base channel (104). The heat distribution plate (132) is a thermal conductor that forms a surface for attaching the heat sink (100) to the thermal source (106). The heat distribution plate (132) is so called because the plate (132) operates to spread out the thermal load along the entire heat sink base (102) even though the thermal source may only generate the thermal load at specific regions along the surface (140) of the thermal source. To provide distribution of the thermal load, the heat distribution plate (132) in the example of FIG. 1 is typically made of a thermal conductor with a high thermal conductivity such as, for example, copper.

The heat distribution plate (132) in the exemplary heat sink (100) of FIG. 1 typically connects to the thermal source (106) by a thermal interface. The thermal interface is a thermally conductive material that reduces the thermal resistance associated with transferring the thermal load from the thermal source (106) to the heat distribution plate (132). The thermal interface between the thermal source (106) and the heat distribution plate (132) has less thermal resistance than could typically be produced by connecting the thermal source (106) directly to the heat distribution plate (132). Decreasing the thermal resistance between the thermal source (106) and the heat distribution plate (132) increases the efficiency of transferring the thermal load from the thermal source (106) to the heat sink (100). The thermal interface may include non-adhesive materials such as, for example, thermal greases, phase change materials, and gap-filling pads. The thermal interface may also include adhesive materials such as, for example, thermosetting liquids, pressure-sensitive adhesive (‘PSA’) tapes, and thermoplastic or thermosetting bonding films.

The exemplary heat sink (100) of FIG. 1 includes heat-dissipating fins (110) mounted on the heat sink base. Each heat-dissipating fin (110) of FIG. 1 has a thermal fin channel (114) inside the heat-dissipating fin. In the example of FIG. 1, each heat-dissipating fin (110) is a thermal conductor comprising two sheets that form two heat-conducting fin walls (142, 144) separated by spacers (146). The spacers (146) of each fin (110) form the thermal fin channel (114). The thermal fin channel (114) is a channel through a heat-dissipating fin capable of passing a thermal transport. The thermal fin channel (114) provides a convective path for transferring the thermal load from the heat sink base (102) to heat-dissipating fins (110) of the heat sink (100). In the exemplary heat sink (100) of FIG. 1, at least a portion (130) of each thermal fin channel (114) extends to the end of the heat-dissipating fin (110) opposite the heat sink base (102). Typically the end of each heat-dissipating fin (110) opposite the heat sink base (102) is the region of the heat sink with the lowest temperature. Extending at least a portion (130) of each thermal fin channel (114) to the end of the heat-dissipating fin (110) opposite the heat sink base (102), therefore, lowers the effective thermal resistance of the exemplary heat sink (100) because such a portion allows a thermal transport to pass through the coolest region of the heat sink (100).

Readers will note that the pattern of the thermal fin channel (114) formed by spacers (146) that is depicted in the exemplary heat sink (100) of FIG. 1 is not a requirement or limitation of the present invention. In fact, other patterns of the thermal fin channel as will occur to those of skill in the art may also be useful in a heat sink for dissipating a thermal load according to embodiments of the present invention. Moreover, there is no requirement that all the thermal fin channels of the fins (110) form the same pattern. In some embodiments of the present invention, the pattern of the thermal fin channels may be reversed in every other fin mounted to the fin mounting plate (116). In other embodiments of the present invention, each thermal fin channel of the fins (110) may have a unique pattern to optimize the dissipation of a thermal load into the environment surrounding the heat sink.

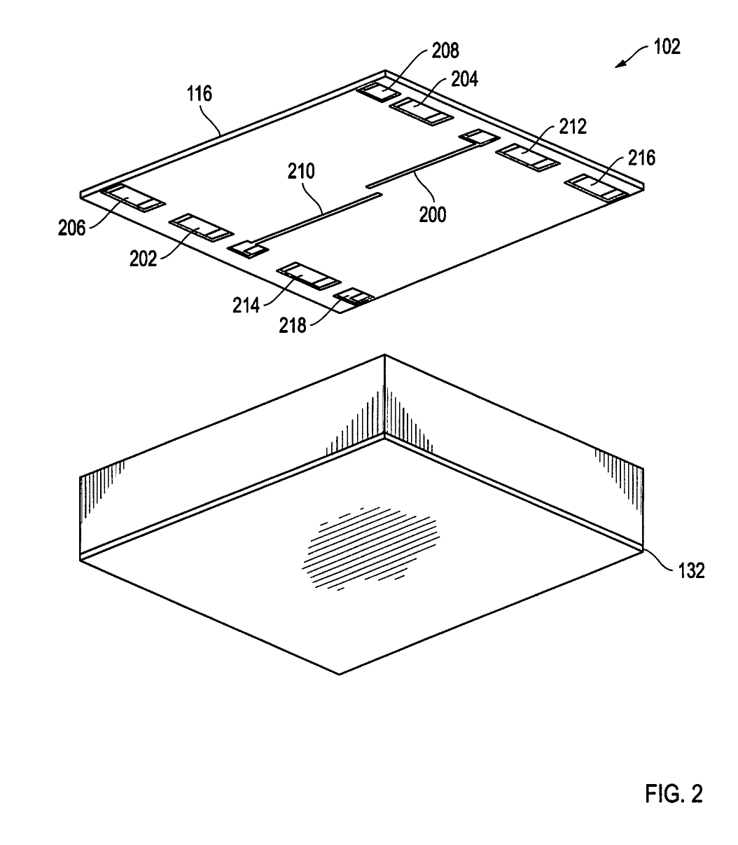

The exemplary heat sink base (102) of FIG. 1 includes a fin mounting plate (116) forming a surface (118) on which the heat-dissipating fins (110) mount. The fin mounting plate (116) has thermal plate channels (120) capable of transferring the thermal transport (112) from one heat-dissipating fin to another heat-dissipating fin (110). The fin mounting plate (116) is described in further detail below with reference FIG. 2.

In the exemplary heat sink (100) of FIG. 1, the thermal base channel (104) and the thermal fin channels (114) are configured to form two loops through the heat sink base (102) and the heat-dissipating fins (110). The loop provides a convective heat path through which a thermal transport may be circulated through the heat sink base (102) and the heat dissipating fins (110). The first loop includes thermal base channel (104) of the heat sink base (102) and the thermal fin channels (114) of heat-dissipating fins (150, 160, 162, 148). The second loop includes another thermal base channel (170) of the heat sink base (102) and the thermal fin channels of heat-dissipating fins (158, 166, 168, 152).

To form first loop, the heat sink base (102) of FIG. 1 includes a base inlet (122), a base outlet (124), a fin inlet (126) on each fin (150, 160, 162, 148), and a fin outlet (128) on each fin (150, 160, 162, 148). The base inlet (122) and the base outlet (124) are openings into the thermal base channel (104). The base inlet (122) is capable of receiving the thermal transport (112) into the thermal base channel (104) from one of the heat-dissipating fins (110). The base outlet (124) is capable of expelling the thermal transport (112) from the thermal base channel (104) to one of the heat-dissipating fins (110). In the example of FIG. 1, the base outlet (124) expels the thermal transport (112) from the thermal base channel (104) to the heat-dissipating fin (148) through a channel in the fin mounting plate (116) that extends from the base outlet (124) to the fin inlet of the heat-dissipating fin (148). The thermal transport (112) then passes through the fins (148, 162, 160, 150). In the example of FIG. 1, the base inlet (122) receives the thermal transport (112) from the heat-dissipating fin (150). Readers will note that the positions of the thermal base channel (104), the base outlet (124), and the base inlet (122) relative to the heat-dissipating fins (110) are not requirements or limitations of the present invention. In fact, the positions of the thermal base channel (104), the base outlet (124), and the base inlet (122) relative to the heat-dissipating fins (110) may be configured in any manner as will occur to those of skill in the art that is useful in a heat-sink for dissipating a thermal load according to embodiments of the present invention.

The fin inlet (126) and the fin outlet (128) are openings into each thermal fin channel (104) in each heat-dissipating fin (110). The fin inlet (126) is capable of receiving the thermal transport (112) into the thermal fin channel (114) from the heat sink base (102). The fin outlet (128) is capable of expelling the thermal transport (112) from the thermal fin channel (114) to the heat sink base (102). In the example of FIG. 1, the fin inlet (126) receives the thermal transport (112) into the thermal fin channel (114) of fin (150) from the heat sink base (102) through one of the thermal plate channels (120). In the example of FIG. 1, the fin outlet (128) expels the thermal transport (112) from the thermal fin channel (114) to the heat sink base (102). In particular, the fin outlet (128) expels the thermal transport (112) from the thermal fin channel (114) into the thermal base channel (104) through the base inlet (122). Although the fin outlet (128) of fin (150) expels the thermal transport (112) into the thermal base channel (104), the fin outlets (not shown) of the other fins (160, 162, 148) in the first loop expel the thermal transport (112) into the thermal plate channels (120) of the heat sink base (102).

The second loop is similar to the first loop. To form the second loop, the heat sink base (102) of FIG. 1 includes a base inlet (154), a base outlet (not shown), a fin inlet (not shown) on each fin (158, 166, 168, 152), and a fin outlet (not shown) on each fin (158, 166, 168, 152). The base inlet (154), the base outlet, the fin inlets on each fin (158, 166, 168, 152), and the fin outlets on each fin (158, 166, 168, 152) are structured similarly to the base outlet, the base inlet, the fin outlets, the fin inlets of the first loop. Readers will note that the two convective loops formed by the exemplary heat sink (100) of FIG. 1 are not requirements or limitations of the present invention. In fact, a heat sink for dissipating a thermal load according to embodiments of the present invention may form any number of convective loops, including a loop for each heat-dissipating fin. In forming a convective loop for each heat-dissipating fin, a heat sink base may be configured to provide the thermal transport to a fin inlet of each fin in parallel and to receive the thermal transport from a fin outlet of each fin in parallel.

The exemplary heat sink (100) of FIG. 1 includes a thermal transport (112) within the thermal base channel (104) and the thermal fin channel (114). The thermal transport is capable of transferring the thermal load from the heat sink base (102) to the heat-dissipating fins (110). As mentioned above, the thermal transport is a thermally conductive fluid. In the example of FIG. 1, the thermal transport (112) is implemented as liquid metal such as, for example, a liquid alloy of gallium, indium, and tin.

The heat sink base (102) in the exemplary heat sink (100) of FIG. 1 includes a thermal transport pump (402). The thermal transport pump (402) is a pump capable of circulating the thermal transport (112) through the first loop described above. In addition to the thermal transport pump (402), the heat sink base (102) also includes another thermal transport pump (not shown) capable of circulating the thermal transport (112) through the second loop described above. In the example of FIG. 1, the thermal transport pump (402) is an electromagnetic pump for circulating the liquid metal through the thermal base channel (104) and the thermal fin channels (114) of fins (150, 160, 162, 148). The thermal transport pump (402) of FIG. 1 includes a power connector (174) for delivering power to the pump (402) from the power bus of a computer system.

In the example of FIG. 1, the thermal transport pump (402) controls the rate at which the thermal transport (112) passes through the thermal base channel (104) and the thermal fin channels (114). The thermal transport pump (402), therefore, affects the rate at which the thermal load is transferred to the heat-dissipating fins (110) and the overall thermal resistance of the heat sink (100). To control the rate at which the thermal transport (112) passes through the thermal base channel (104) and the thermal fin channels (114), the exemplary heat sink (100) of FIG. 1 includes a pump governor (172). The pump governor (172) is computer hardware capable of measuring the thermal load from the thermal source (106) and controlling the thermal transport pump (172) in dependence upon the measured thermal load. The pump governor (172) may be implemented as a thermistor along with circuit logic to vary the voltage supplied to the thermal transport pump (402). Such an implementation, however, is for explanation and not for limitation. In fact, the pump governor (172) may also be implemented using a more sophisticated Application Specific Integrated Circuit (‘ASIC’).

As mentioned above, the exemplary heat sink base of FIG. 1 includes a fin mounting plate forming a surface on which the heat-dissipating fins mount. For further explanation, therefore, FIG. 2 sets forth an exploded perspective view of an exemplary heat sink base (102) useful in a heat sink for dissipating a thermal load according to embodiments of the present invention that includes a fin mounting plate (116) forming a surface on which the heat-dissipating fins (110) mount.

The fin mounting plate (116) in the example of FIG. 2 includes thermal plate channels (200, 202, 204, 206, 208, 210, 212, 214, 216, 218). The thermal plate channels are channels in the fin mounting plate (116) capable of passing a thermal transport. Although the exploded view of FIG. 2 illustrates the thermal plate channels as having openings on both the top and bottom of the fin mounting plate (116), when the fin mounting plate (116) is affixed to the other portions of the heat sink base as depicted in FIG. 1, the only openings for the thermal plate channels are the opening on the top of the fin mounting plate (116). The openings on the top of the fin mounting plate (116) allow a thermal transport to pass between a thermal base channel of the heat sink base (102) and one of the heat-dissipating fins or to pass from one heat-dissipating fin to another heat dissipating fin.

In the example of FIG. 2, thermal plate channels (200, 208, 210, 218) are capable of passing a thermal transport between a thermal base channel of the heat sink base (102) and one of the heat-dissipating fins. The thermal plate channel (200) of FIG. 2 is capable of passing a thermal transport between the heat sink base (102) and the heat-dissipating fin (148) depicted in FIG. 1. The thermal plate channel (208) of FIG. 2 is capable of passing a thermal transport between the heat sink base (102) and the heat-dissipating fin (150) depicted in FIG. 1. The thermal plate channel (210) of FIG. 2 is capable of passing a thermal transport between the heat sink base (102) and the heat-dissipating fin (158) depicted in FIG. 1. The thermal plate channel (218) of FIG. 2 is capable of passing a thermal transport between the heat sink base (102) and the heat-dissipating fin (152) depicted in FIG. 1.

In the example of FIG. 2, thermal plate channels (202, 204, 206, 212, 214, 216) are capable of passing the thermal transport (112) from one heat-dissipating fin to another heat-dissipating fin. The thermal plate channel (202) of FIG. 2 is capable of passing a thermal transport from the heat-dissipating fin (148) depicted in FIG. 1 to the heat-dissipating fin (162) depicted in FIG. 1. The thermal plate channel (204) of FIG. 2 is capable of passing a thermal transport from the heat-dissipating fin (162) depicted in FIG. 1 to the heat-dissipating fin (160) depicted in FIG. 1. The thermal plate channel (206) of FIG. 2 is capable of passing a thermal transport from the heat-dissipating fin (160) depicted in FIG. 1 to the heat-dissipating fin (150) depicted in FIG. 1. The thermal plate channel (212) of FIG. 2 is capable of passing a thermal transport from the heat-dissipating fin (158) depicted in FIG. 1 to the heat-dissipating fin (166) depicted in FIG. 1. The thermal plate channel (214) of FIG. 2 is capable of passing a thermal transport from the heat-dissipating fin (166) depicted in FIG. 1 to the heat-dissipating fin (168) depicted in FIG. 1. The thermal plate channel (216) of FIG. 2 is capable of passing a thermal transport from the heat-dissipating fin (168) depicted in FIG. 1 to the heat-dissipating fin (152) depicted in FIG. 1.

The exemplary heat sink base (102) of FIG. 2 also includes a heat distribution plate (132). The heat distribution plate (132) of FIG. 2 is adjacent to the thermal source (not shown) and adjacent to the thermal base channel (not shown). The heat distribution plate (132) of FIG. 2 is structured in the same manner as the heat distribution plate (132) described with reference to FIG. 1.

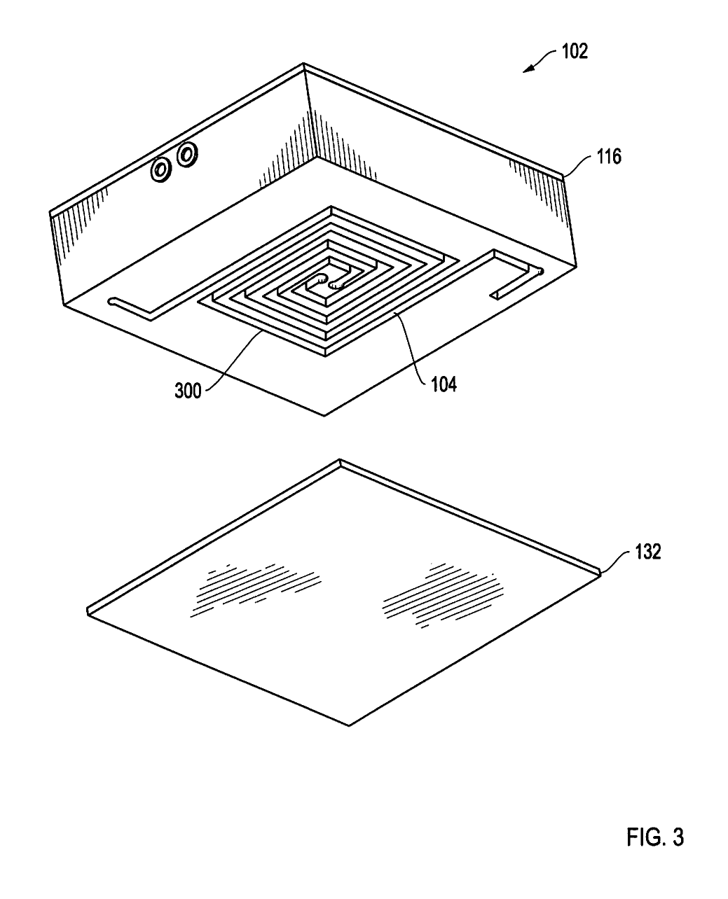

As mentioned above, the exemplary heat sink base of FIG. 1 includes a thermal base channel inside the heat sink base. For further explanation, therefore, FIG. 3 sets forth an exploded perspective view of an exemplary heat sink base (102) useful in a heat sink for dissipating a thermal load according to embodiments of the present invention that includes a thermal base channel (104) inside the heat sink base (102).

In the example of FIG. 3, at least a portion (300) of the thermal base channel (104) resides in the heat sink base (102) adjacent to the thermal source (not shown). The portion (300) of the thermal base channel (104) that resides in the heat sink base (102) adjacent to the thermal source is configured in a swirling pattern illustrated in FIG. 3. Although FIG. 3 depicts the portion (300) of the thermal base channel (104) that resides in the heat sink base (102) adjacent to the thermal source configured in a swirling pattern, such a depiction is for explanation and not for limitation. In fact, the portion (300) of the thermal base channel (104) that resides in the heat sink base (102) adjacent to the thermal source may be configured in any pattern as will occur to those of skill in the art. Because the thermal transport resides within the thermal base channel (104), configuring a portion (300) of the thermal base channel (104) adjacent to the thermal source typically optimizes the transfer of the thermal load from the thermal source into the thermal transport within the thermal base channel (104).

The exemplary heat sink base (102) of FIG. 3 also includes a heat distribution plate (132). The heat distribution plate (132) of FIG. 3 is adjacent to the thermal source (not shown) and adjacent to the thermal base channel (104). The heat distribution plate (132) of FIG. 3 is structured in the same manner as the heat distribution plate (132) described with reference to FIG. 1.

The exemplary heat sink base (102) of FIG. 3 also includes a fin mounting plate (116). The fin mounting plate (116) forms a surface on which the heat-dissipating fins (not shown) mount. The fin mounting plate (116) of FIG. 3 is structured in the same manner as the fin mounting plate (116) described with reference to FIG. 1.

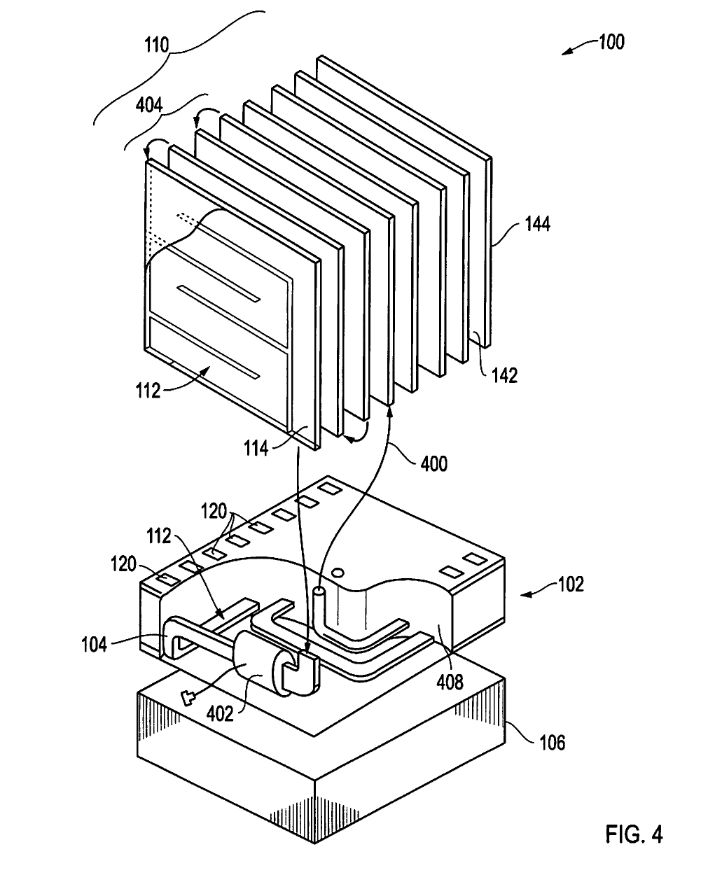

As mentioned above, the thermal base channel and the thermal fin channels illustrated in FIG. 1 are configured to form two loops through the heat sink base and the heat-dissipating fins. For further explanation, therefore, FIG. 4 sets forth an exploded perspective view of a further exemplary heat sink (100) for dissipating a thermal load according to embodiments of the present invention in which the thermal base channel (104) and the thermal fin channels (114) are configured to form a loop (400) through the heat sink base (102) and the heat-dissipating fins (404).

The exemplary heat sink (100) of FIG. 4 is similar to the exemplary heat sink of FIG. 1. That is, the exemplary heat sink (100) of FIG. 4 is similar to the exemplary heat sink of FIG. 1 in that the exemplary heat sink (100) of FIG. 4 includes a heat sink base (102) having a thermal base channel (104) inside the heat sink base. The heat sink base (102) of FIG. 4 is capable of receiving a thermal load from a thermal source (106). The exemplary heat sink (100) of FIG. 4 also includes heat-dissipating fins (110) mounted on the heat sink base (102). Each heat-dissipating fin (110) has a thermal fin channel (114) inside the heat-dissipating fin. The exemplary heat sink (100) of FIG. 4 also includes a thermal transport (112) within the thermal base channel (104) and the thermal fin channel (114). The thermal transport (112) of FIG. 4 is capable of transferring the thermal load from the heat sink base (102) to the heat-dissipating fins (110).

In the example of FIG. 4, the loop (400) provides a convective heat path for passing a thermal transport (112). The loop (400) is formed by the thermal base channel (104), the thermal fin channels (114) in each of the heat-dissipating fins (404), and the thermal plate channels (120). The thermal transport (112) passes through the loop (104) by passing through the thermal base channel (104), the thermal fin channels (114) in each of the heat-dissipating fins (404), and the thermal plate channels (120). As the thermal transport (112) passes through the loop (104), the thermal load is transferred from the heat sink base (102) to the heat-dissipating fins (404) through the convective heat path loop (400).

The heat sink base (102) in the exemplary heat sink (100) of FIG. 1 includes a thermal transport pump (402). The thermal transport pump (402) is a pump capable of circulating the thermal transport (112) through the loop (402). In the example of FIG. 1, the thermal transport (112) is liquid metal such as, for example, a liquid alloy of gallium, indium, and tin, and the thermal transport pump (402) is an electromagnetic pump.

As mentioned above, the exemplary heat sink (100) may transfer the thermal load from the heat sink base (102) to the heat-dissipating fins (110) through a conductive heat path in addition to a convective heat path. The exemplary heat sink (100) provides a conductive heat path through the heat-conducting base region (408) and two heat-conducting fin walls (142, 144) for each heat-dissipating fin (110). The heat-conducting base region (408) of the exemplary heat sink (100) of FIG. 4 is the region of the heat sink base (102) from which the thermal base channel (104) is formed. The heat-conducting fin walls (142, 144) for each heat-dissipating fin (110) mount on the heat sink base (102). The thermal load from the thermal source (106) passes through the heat sink base (102) and through the fin walls (142, 144) for dissipation into the environment surrounding the heat sink (100).

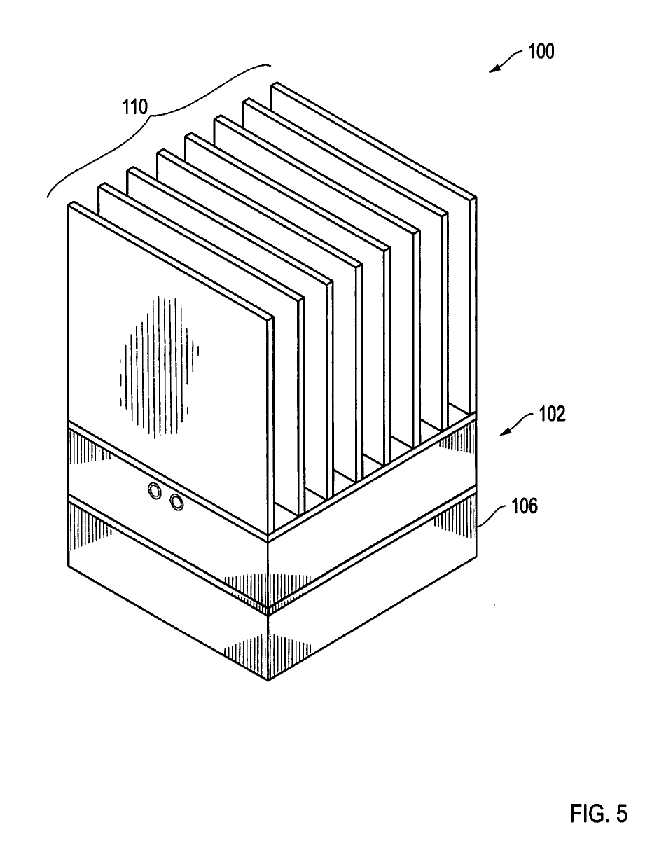

FIGS. 1 and 4 provide an exploded perspective view of an exemplary heat sink for dissipating a thermal load according to embodiments of the present invention. Turning now to FIG. 5, FIG. 5 sets forth a perspective view of a further exemplary heat sink (100) for dissipating a thermal load according to embodiments of the present invention that is installed on a thermal source (106). As mentioned above, the thermal source (106) is an integrated circuit package such as, for example, a computer processor or memory module.

The exemplary heat sink (100) of FIG. 5 is similar to the exemplary heat sink of FIG. 1. That is, the exemplary heat sink (100) of FIG. 5 is similar to the exemplary heat sink of FIG. 1 in that the exemplary heat sink (100) of FIG. 5 includes a heat sink base (102) having a thermal base channel inside the heat sink base. The heat sink base (102) of FIG. 5 is capable of receiving a thermal load from a thermal source (106). The exemplary heat sink (100) of FIG. 5 also includes heat-dissipating fins (110) mounted on the heat sink base (102). Each heat-dissipating fin (110) has a thermal fin channel inside the heat-dissipating fin. The exemplary heat sink (100) of FIG. 5 also includes a thermal transport within the thermal base channel and the thermal fin channel. The thermal transport of FIG. 5 is capable of transferring the thermal load from the heat sink base (102) to the heat-dissipating fins (110).

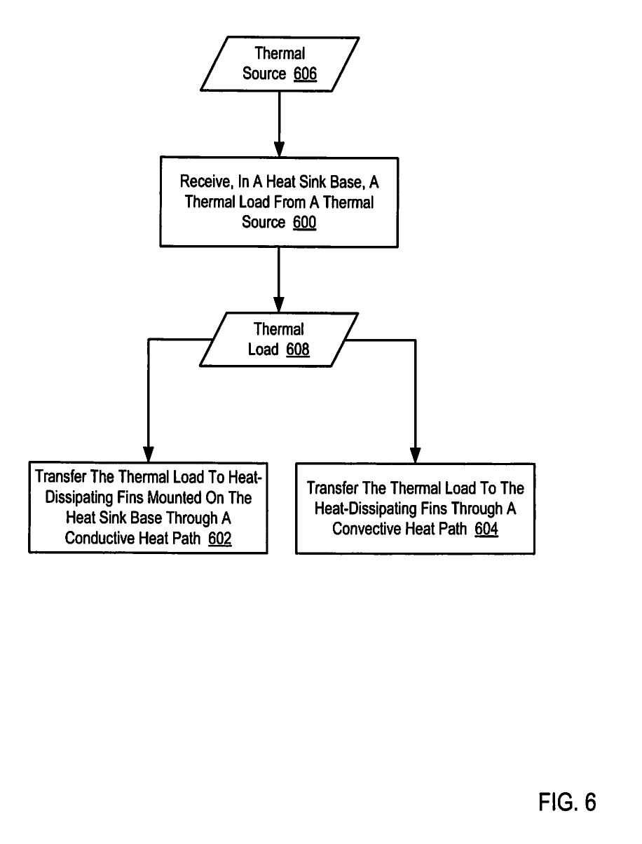

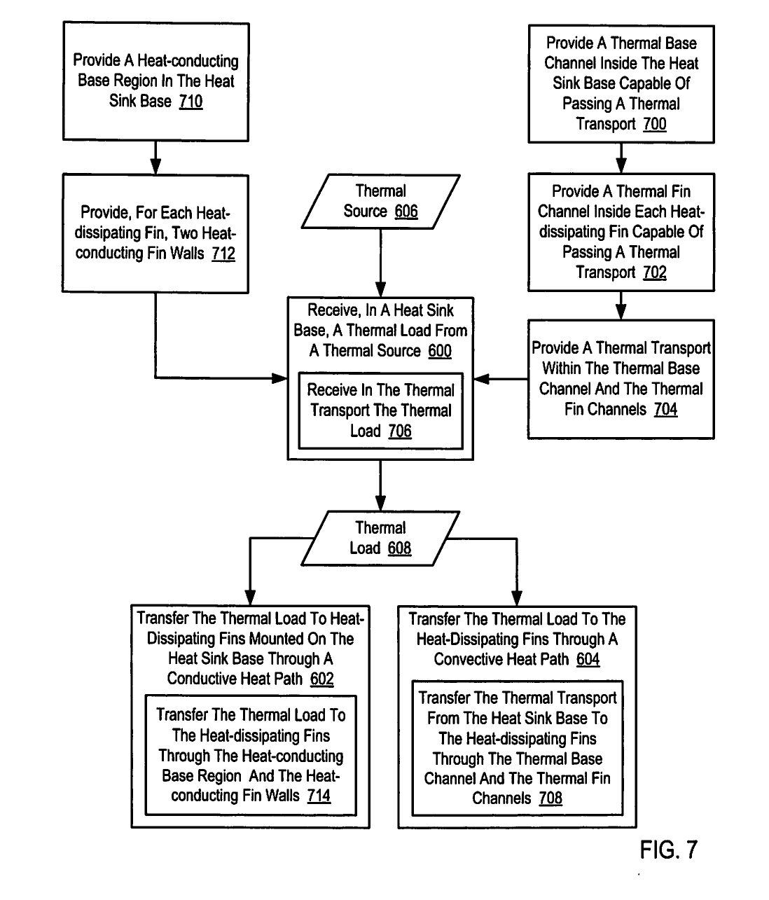

As mentioned above, exemplary methods for parallel dissipation of a thermal load according to embodiments of the present invention are described with reference to the accompanying drawings. For further explanation, FIG. 6 sets forth a flow chart illustrating an exemplary method for parallel dissipation of a thermal load according to embodiments of the present invention. The method of FIG. 6 includes receiving (600), in a heat sink base, a thermal load (608) from a thermal source (606). The thermal source (606) of FIG. 6 represents an integrated circuit package such as, for example, a computer processor or memory chip. The thermal load (608) of FIG. 6 represents the thermal energy generated by the thermal source (606). Receiving (600), in a heat sink base, a thermal load (608) from a thermal source (606) according to the method of FIG. 6 may be carried out by receiving in a thermal transport the thermal load (608) as described below with reference to FIG. 7.

Parallel dissipation of a thermal load according to embodiments of the present invention may be carried out simultaneously through a conductive heat path and a convective heat path. Regarding the conductive heat path, the method of FIG. 6 also includes transferring (602) the thermal load (608) to heat-dissipating fins mounted on the heat sink base through a conductive heat path. The conductive heat path is the path through the solid portions of a heat sink through which the thermal load is transferred by heat conduction. A conductive heat path may include the heat-conducting base region and the heat-conducting fin walls of the heat sink described above with reference to FIG. 4. Transferring (602) the thermal load (608) to heat-dissipating fins mounted on the heat sink base through a conductive heat path according to the method of FIG. 6 may be carried out by transferring the thermal load to the heat-dissipating fins through the heat conducting base region and the heat-conducting fin walls as described below with reference to FIG. 7.

Regarding the convective heat path, the method of FIG. 6 also includes transferring (604) the thermal load (608) to the heat-dissipating fins through a convective heat path. The convective heat path is the path through a liquid portion of a heat sink that carries the thermal load from the base of the heat sink to the heat-dissipating fins. An example of a convective heat path may include the thermal base channel and the thermal fin channels that carry the thermal load from the base of the heat sink to the heat-dissipating fins in the exemplary heat sink described with reference to FIG. 1. Transferring (604) the thermal load (608) to the heat-dissipating fins through a convective heat path may be carried out by transferring a thermal transport from the heat sink base to the heat-dissipating fins through the thermal base channel and the thermal fin channels as described below with reference to FIG. 7.

As mentioned above, transferring a thermal load to heat-dissipating fins through a convective heat path may be carried out by transferring a thermal transport from the heat sink base to the heat-dissipating fins through a thermal base channel and thermal fin channels. For further explanation, FIG. 7 sets forth a flow chart illustrating a further exemplary method for parallel dissipation of a thermal load according to embodiments of the present invention that includes transferring (708) the thermal transport from the heat sink base to the heat-dissipating fins through the thermal base channel and the thermal fin channels.

The method of FIG. 7 is similar to the method of FIG. 6. That is, the method of FIG. 7 is similar to the method of FIG. 6 in that the method of FIG. 7 includes receiving (600), in a heat sink base, a thermal load (608) from a thermal source (606), transferring (602) the thermal load (608) to heat-dissipating fins mounted on the heat sink base through a conductive heat path, and transferring (604) the thermal load (608) to the heat-dissipating fins through a convective heat path. The example of FIG. 7 is also similar to the example of FIG. 6 in that the example of FIG. 7 also includes the thermal source (606) and the thermal load (608).

As mentioned above, parallel dissipation of a thermal load according to embodiments of the present invention may be carried out simultaneously through a conductive heat path and a convective heat path. Regarding the conductive heat path, the method of FIG. 7 includes providing (710) a heat-conducting base region in the heat sink base and providing (712), for each heat-dissipating fin, two heat-conducting fin walls. An example of the heat-conducting base region may include the heat-conducting base region described with reference to FIG. 4. Examples of a heat-conducting fin wall may include the heat-conducting fin walls described with reference to FIGS. 1 and 4.

In the method of FIG. 7, transferring (602) the thermal load (608) to heat-dissipating fins mounted on the heat sink base through a conductive heat path includes transferring (714) the thermal load to the heat-dissipating fins through the heat-conducting base region and the heat-conducting fin walls. Transferring (714) the thermal load to the heat-dissipating fins through the heat-conducting base region and the heat-conducting fin walls advantageously passes the thermal load to the heat-dissipating fins for dissipating the thermal load even if the parallel convective heat path is blocked.

Regarding the convective heat path, the method of FIG. 7 also includes providing (700) a thermal base channel inside the heat sink base capable of passing a thermal transport. An example of a thermal base channel may include the thermal base channel described above with reference to FIG. 1.

The method of FIG. 7 also includes providing (702) a thermal fin channel inside each heat-dissipating fin capable of passing a thermal transport. An example of a thermal fin channel may include the thermal fin channel described above with reference to FIG. 1.

The method of FIG. 7 also includes providing (704) a thermal transport within the thermal base channel and the thermal fin channels. As mentioned above, a thermal transport is a thermally conductive fluid such as, for example, liquid metal or the family of perfluorinated liquids developed by 3M™ generally referred to as Fluorinert™. In the example of FIG. 7, the thermal transport is implemented as liquid metal such as, for example, a liquid alloy of gallium, indium, and tin.

In the method of FIG. 7, receiving (600), in a heat sink base, a thermal load (608) from a thermal source (606) includes receiving (706) in the thermal transport the thermal load. Receiving (706) in the thermal transport the thermal load may be carried out by transferring the thermal load (608) into the thermal transport by thermal conduction.

In the method of FIG. 7, transferring (604) the thermal load (608) to the heat-dissipating fins through a convective heat path includes transferring (708) the thermal transport from the heat sink base to the heat-dissipating fins through the thermal base channel and the thermal fin channels. Transferring (708) the thermal transport from the heat sink base to the heat-dissipating fins through the thermal base channel and the thermal fin channels may be carried out by pumping by a thermal transport pump the thermal transport from the heat sink base to the heat-dissipating fins through the thermal base channel and the thermal fin channels. In the example of FIG. 7, the thermal transport pump may be implemented as an electromagnetic pump.

Readers will note from above, that thermal base channel and the thermal fin channels may be configured to form a loop through the heat sink base and the heat-dissipating fins. In such a configuration, transferring (604) the thermal load (608) to the heat-dissipating fins through a convective heat path according to the method of FIG. 7 may be carried out by circulating by a thermal transport pump the thermal transport through the loop.

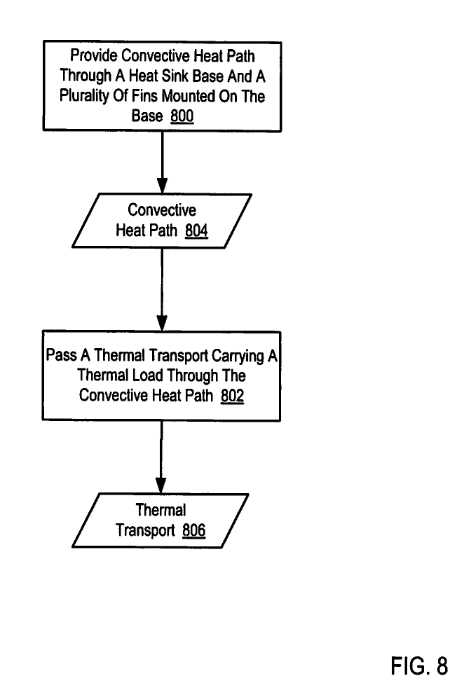

As mentioned above, exemplary methods for convective dissipation of a thermal load according to embodiments of the present invention are described with reference to the accompanying drawings. For further explanation, FIG. 8 sets forth a flow chart illustrating an exemplary method for convective dissipation of a thermal load according to embodiments of the present invention.

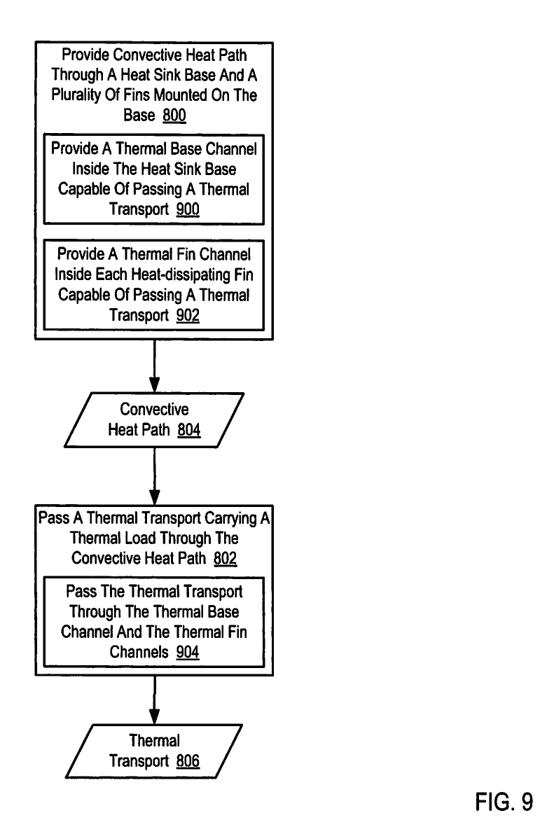

The method of FIG. 8 includes providing (800) a convective heat path (804) through a heat sink base and a plurality of fins mounted on the base. The convective heat path (804) is the path through a liquid portion of a heat sink that carries the thermal load from the base of the heat sink to the heat-dissipating fins. An example of a convective heat path may include the convective heat path loop described above with reference to FIGS. 1 and 4. Providing (800) a convective heat path (804) through a heat sink base and a plurality of fins mounted on the base according to the method of FIG. 8 may be carried out by providing a thermal base channel inside the heat sink base capable of passing a thermal transport, and providing a thermal fin channel inside each heat-dissipating fin capable of passing a thermal transport as described below with reference to FIG. 9.

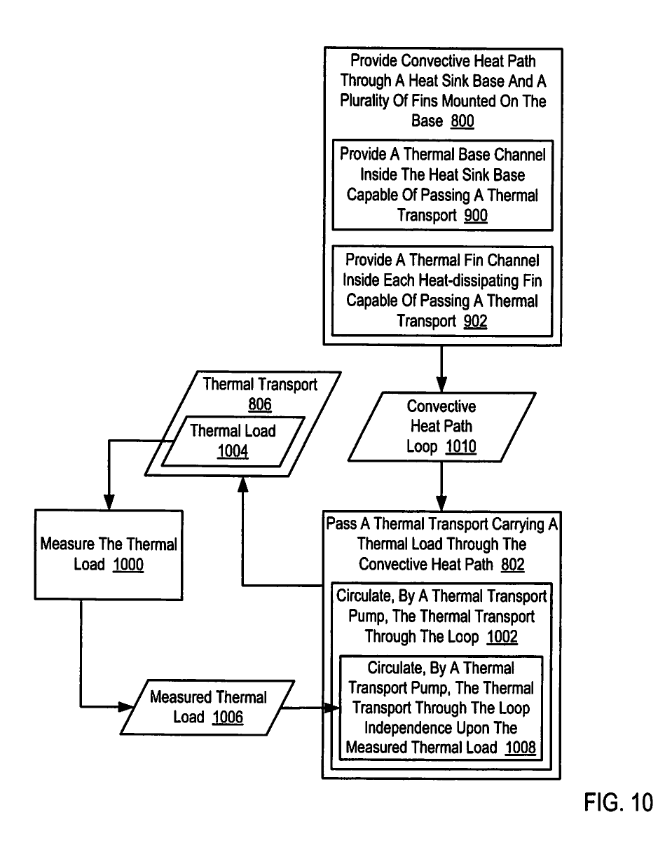

The method of FIG. 8 also includes passing (802) a thermal transport (806) carrying a thermal load through the convective heat path (804). As mentioned above, a thermal transport (806) is a thermally conductive fluid such as, for example, liquid metal or the family of perfluorinated liquids developed by 3M™ generally referred to as Fluorinert™. In the example of FIG. 8, the thermal transport is implemented as liquid metal such as, for example, a liquid alloy of gallium, indium, and tin. Passing (802) a thermal transport (806) carrying a thermal load through the convective heat path (804) according to the method of FIG. 8 may be carried out by passing the thermal transport (806) through the thermal base channel and the thermal fin channels or by circulating, by a thermal transport pump, the thermal transport through a loop as described below with reference to FIGS. 9 and 10.

As mentioned above, passing a thermal transport carrying a thermal load through the convective heat path may be carried out by passing the thermal transport through the thermal base channel and the thermal fin channels. For further explanation, therefore, FIG. 9 sets forth a flow chart illustrating a further exemplary method for convective dissipation of a thermal load according to embodiments of the present invention that includes passing (904) the thermal transport (806) through the thermal base channel and the thermal fin channels.

The method of FIG. 9 is similar to the method of FIG. 8. That is, the method of FIG. 9 is similar to the method of FIG. 8 in that the method of FIG. 9 includes providing (800) a convective heat path (804) through a heat sink base and a plurality of fins mounted on the base, and passing (802) a thermal transport (806) carrying a thermal load through the convective heat path. The example of FIG. 9 is also similar to the example of FIG. 8 in that the example of FIG. 9 includes the convective heat path (804) and the thermal transport (806). In the example of FIG. 9, the thermal transport is implemented as liquid metal such as, for example, a liquid alloy of gallium, indium, and tin.

The method of FIG. 9 differs from the method of FIG. 8 in that providing (800) a convective heat path (804) through a heat sink base and a plurality of fins mounted on the base according to the method of FIG. 9 includes providing (900) a thermal base channel inside the heat sink base capable of passing a thermal transport (806). An example of a thermal base channel may include the thermal base channel as described above with reference to FIG. 1.

In the method of FIG. 9, providing (800) a convective heat path (804) through a heat sink base and a plurality of fins mounted on the base includes providing (902) a thermal fin channel inside each heat-dissipating fin capable of passing a thermal transport (806). An example of a thermal fin channel may include a thermal fin channel as described above with reference to FIG. 1.

In the method of FIG. 9, passing (802) a thermal transport (806) carrying a thermal load through the convective heat path includes passing (904) the thermal transport (806) through the thermal base channel and the thermal fin channels. Passing (904) the thermal transport (806) through the thermal base channel and the thermal fin channels may be carried out by pumping by a thermal transport pump the thermal transport (806) through the thermal base channel and the thermal fin channels. In the example of FIG. 9, the thermal transport pump may be implemented as an electromagnetic pump.

Readers will note from above, that thermal base channel and the thermal fin channels may be configured to form a convective heat path loop through the heat sink base and the heat-dissipating fins. Readers will further note from above that the rate at which the thermal transport passes through the loop affects the overall thermal resistance of a heat sink. Because the overall thermal resistance of the heat sink affects the temperature of the thermal source to which the heat sink is attached, controlling the rate at which the thermal transport passes through the loop may be used to control the temperature of the thermal source. As the temperature increases, the rate at which the thermal transport passes through the loop may be increased in an attempt to cool down the thermal source. For further explanation, FIG. 10 sets forth a flow chart illustrating a further exemplary method for convective dissipation of a thermal load according to embodiments of the present invention that includes circulating (1008), by a thermal transport pump, a thermal transport (806) through a loop (1010) independence upon the measured thermal load (1006)

The method of FIG. 10 is similar to the method of FIG. 9. That is, the method of FIG. 10 is similar to the method of FIG. 9 in that the method of FIG. 10 includes providing (800) a convective heat path (804) through a heat sink base and a plurality of fins mounted on the base, providing (900) a thermal base channel inside the heat sink base capable of passing a thermal transport (806), providing (902) a thermal fin channel inside each heat-dissipating fin capable of passing a thermal transport (806), and passing (802) a thermal transport (806) carrying a thermal load (1004) through the convective heat path. The thermal transport (806) of FIG. 10 represents a thermally conductive fluid such as, for example, liquid metal or the family of perfluorinated liquids developed by 3M™ generally referred to as Fluorinert™. The thermal load (1004) of FIG. 10 represents the thermal energy generated by a thermal source and absorbed into the thermal transport (806) by conduction.

The method of FIG. 10 differs from the method of FIG. 9 in that the method of FIG. 10 includes measuring (1000) the thermal load (1004). The measured thermal load (1006) represents a measurement of the thermal load such as, for example, an electric voltage signal representing thermal energy. Measuring (1000) the thermal load (1004) according to the method of FIG. 10 may be carried out by identifying the thermal energy of the thermal load using an electrical voltage signal provided by a sensor such as, for example, a thermistor.

In the method of FIG. 10, passing (802) a thermal transport (806) carrying a thermal load through the convective heat path includes circulating (1002), by a thermal transport pump, the thermal transport (806) through a convective heat path loop (1010). The convective heat path loop (1010) is the loop formed by the thermal base channel and the thermal fins channels through a heat sink for transferring a thermal transport from the base of the heat sink to the heat-dissipating fins. In the method of FIG. 10, circulating (1010), by a thermal transport pump, the thermal transport through the loop (1010) includes circulating (1008), by a thermal transport pump, the thermal transport (806) through the loop (1010) independence upon the measured thermal load (1006). Circulating (1008), by a thermal transport pump, the thermal transport (806) through the loop (1010) independence upon the measured thermal load (1006) may be carried out by providing a voltage signal to the thermal transport pump in dependence upon the measured thermal load (1006).

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A heat sink for dissipating a thermal load, the heat sink comprising:
a heat sink base having a thermal base channel inside the heat sink base, the heat sink base capable of receiving a thermal load from a thermal source;
heat-dissipating fins mounted on the heat sink base, each heat-dissipating fin having a thermal fin channel inside the heat-dissipating fin; and
a thermal transport within the thermal base channel and the thermal fin channel, the thermal transport capable of transferring the thermal load from the heat sink base to the heat-dissipating fins.

2. The heat sink of claim 1 wherein:
the thermal base channel and the thermal fin channels are configured to form a loop through the heat sink base and the heat-dissipating fins; and
the heat sink base further comprises a thermal transport pump capable of circulating the thermal transport through the loop.

3. The heat sink of claim 2 wherein:
the thermal transport is liquid metal; and
the thermal transport pump is an electromagnetic pump.

4. The heat sink of claim 2 further comprising a pump governor capable of controlling the thermal transport pump in dependence upon a measurement of the thermal load.

5. The heat sink of claim 1 wherein at least a portion of the thermal base channel resides in the heat sink base adjacent to the thermal source.

6. The heat sink of claim 1 wherein at least a portion of each thermal fin channel extends to the end of the heat-dissipating fin opposite the heat sink base.

7. The heat sink of claim 1 wherein the heat sink base further comprises a heat distribution plate adjacent to the thermal source and adjacent to the thermal base channel.

8. The heat sink of claim 1 wherein the heat sink base further comprises:
a base inlet capable of receiving the thermal transport into the thermal base channel from one of the heat-dissipating fins; and
a base outlet capable of expelling the thermal transport from the thermal base channel to one of the heat-dissipating fins.

9. The heat sink of claim 1 wherein the heat sink base further comprises:
a fin mounting plate forming a surface on which the heat-dissipating fins mount, the fin mounting plate having thermal plate channels capable of passing the thermal transport from one heat-dissipating fin to another heat-dissipating fin.

10. The heat sink of claim 1 wherein each heat-dissipating fin further comprises:
a fin inlet capable of receiving the thermal transport into the thermal fin channel from the heat sink base; and
a fin outlet capable of expelling the thermal transport from the thermal fin channel to the heat sink base.

11. A method for parallel dissipation of a thermal load, the method comprising:
receiving, in a heat sink base, a thermal load from a thermal source;
transferring the thermal load to heat-dissipating fins mounted on the heat sink base through a conductive heat path; and
transferring the thermal load to the heat-dissipating fins through a convective heat path.

12. The method of claim 11 further comprising:
providing a thermal base channel inside the heat sink base capable of passing a thermal transport;
providing a thermal fin channel inside each heat-dissipating fin capable of passing a thermal transport; and
providing a thermal transport within the thermal base channel and the thermal fin channels;
wherein receiving, in a heat sink base, a thermal load from a thermal source further comprises receiving in the thermal transport the thermal load; and
wherein transferring the thermal load to the heat-dissipating fins through the convective heat path further comprises transferring the thermal transport from the heat sink base to the heat-dissipating fins through the thermal base channel and the thermal fin channels.

13. The method of claim 12 wherein:
the thermal base channel and the thermal fin channels are configured to form a loop through the heat sink base and the heat-dissipating fins; and
transferring the thermal load to the heat-dissipating fins through the convective heat path further comprises circulating by a thermal transport pump the thermal transport through the loop.

14. The method of claim 13 wherein:
the thermal transport is liquid metal; and
the thermal transport pump is an electromagnetic pump.

15. The method of claim 11 further comprising:
providing a heat-conducting base region in the heat sink base; and
providing, for each heat-dissipating fin, two heat-conducting fin walls;
wherein transferring the thermal load to the heat-dissipating fins mounted on the heat sink base through the conductive heat path further comprises transferring the thermal load to the heat-dissipating fins through the heat-conducting base region and the heat-conducting fin walls.

16. A method for convective dissipation of a thermal load, the method comprising:
providing a convective heat path through a heat sink base and a plurality of fins mounted on the base; and
passing a thermal transport carrying a thermal load through the convective heat path.

17. The method of claim 16 wherein:
providing a convective heat path through a heat sink base and a plurality of fins mounted on the base further comprises:
providing a thermal base channel inside the heat sink base capable of passing a thermal transport, and
providing a thermal fin channel inside each heat-dissipating fin capable of passing a thermal transport; and
passing a thermal transport carrying a thermal load through the convective heat path further comprises passing the thermal transport through the thermal base channel and the thermal fin channels.

18. The method of claim 17 wherein:
the thermal base channel and the thermal fin channels are configured to form a loop through the heat sink base and the heat-dissipating fins; and
passing a thermal transport carrying a thermal load through the convective heat path further comprises circulating, by a thermal transport pump, the thermal transport through the loop.

19. The method of claim 18 wherein:
the thermal transport is liquid metal; and
the thermal transport pump is an electromagnetic pump.

20. The method of claim 18 further comprising:
measuring the thermal load;
wherein circulating, by a thermal transport pump, the thermal transport through the loop further comprises circulating, by a thermal transport pump, the thermal transport through the loop independence upon the measured thermal load.
